(19) United States
(12) Patent Application Publication
(10) Pub. No.: US 2014/0103096 A1
(43) Pub. Date: Apr. 17, 2014

(54) WIRE BONDING MACHINE AND METHOD FOR TESTING WIRE BOND CONNECTIONS

(71) Applicants: Hanmin Zhang, Tianjin (CN); Qingchun He, Tianjin (CN); Liqiang Xu, Tianjin (CN); Fei Zong, Tianjin (CN)

(72) Inventors: Hanmin Zhang, Tianjin (CN); Qingchun He, Tianjin (CN); Liqiang Xu, Tianjin (CN); Fei Zong, Tianjin (CN)

(21) Appl. No.: 13/865,185

(22) Filed: Apr. 17, 2013

(30) Foreign Application Priority Data
Oct. 15, 2012 (CN) 201210597852.4

(51) Int. Cl. H01L 23/00

(52) U.S. Cl. CPC H01L 24/85
USPC 228/104; 228/4.5

(57) ABSTRACT

A wire bonding machine and a method for testing wire bond connection s using the wire bonding machine. The method includes providing a semiconductor assembly that has a semiconductor die mounted to a substrate, each of which has bonding pads. The method includes bonding a wire to one of the bonding pads to form a first wire bond. A shear force then is applied to the first wire bond. A fault signal is generated when a sensor detects the first wire bond moving during application of the shear force.

### BACKGROUND OF THE INVENTION

The present invention relates generally to semiconductor device assembly and, more particularly, to a wire bonding machine and method for testing wire bond connection s.

Semiconductor devices are often formed with a semiconductor die mounted on a non-conductive substrate (die carrier). Bonding pads on the die are wire bonded to bonding pads on the substrate to allow for external electrical connection of the die to circuit boards and the like. After wire bonding, the semiconductor die and bond wires are encapsulated in a compound such as a plastics material leaving external connectors of the substrate exposed for external electrical connection.

Wire bonding is a widely used technique for providing electrical connection between the semiconductor die and substrate. The integrity, or quality, of wire bond interconnections formed between the die bonding pads and the substrate bonding pads may be evaluated (tested) visually, electrically or mechanically.

Visual testing typically relies on human inspection and this type of testing has the potential for allowing poor quality bonds to be accepted due to human operator fatigue. In contrast, the reliability of electrical testing is not dependent upon operator fatigue, however, electrical testing may not necessarily identify poor quality bonds that intermittently give a reasonable low impedance characteristic.

Mechanical testing is a useful alternative to electrical testing and such testing includes peel strength testing in which the peel strength of a wire bond provides an indication of the likelihood of bond failure. Typically, the peel strength test is performed by placing a hook under the bond wire at a location near the wire bond under test. The hook pulls on the bond wire thereby providing a tension force to the wire bond under test.

Although, peel strength testing of wire bonds provides a relatively reliable test quality for ball bonds and the like, it is not necessarily suitable for all types of bonds such as wedge bonds. Furthermore, peel strength testing requires an additional gripping tool or hook to provide the tension force to the wire bond. This gripping tool requires precise control circuitry for accurate positioning and this positioning can be relatively time consuming.

### BRIEF DESCRIPTION OF THE DRAWINGS

The invention, together with objects and advantages thereof, may best be understood by reference to the following description of preferred embodiments together with the accompanying drawings in which:

FIG. 1 is a plan view of a conventional semiconductor assembly;

FIG. 2 is a side view of the semiconductor assembly of FIG. 1;

FIG. 3 is a schematic block diagram of a wire bonding machine in accordance with a preferred embodiment of the present invention;

FIG. 4 illustrates part of a wire bonding tool of the machine of FIG. 3 when performing wire bonding of the semiconductor assembly of FIG. 1;

FIG. 5 illustrates part of a wire bond tool head performing wire bonding in accordance with a preferred embodiment of the present invention;

FIG. 6 is a cross-sectional side view of part of the wire bond tool head of FIG. 5 through 6-6′;

FIG. 7 is a flow chart illustrating a method for testing a wire bond connection in accordance with a preferred embodiment of the present invention; and

FIG. 8 is a flow chart illustrating a method for testing a wire bond connection in accordance with another preferred embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practiced. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that system, circuit, device components and method steps that comprises a list of elements or steps does not include only those elements but may include other elements or steps not expressly listed or inherent to such system, circuit, device components or steps. An element or step proceeded by “comprises . . . a” does not, without more constraints, preclude the existence of additional identical elements or steps that comprises the element or step.

In one embodiment of the present invention there is provided a method for testing a wire bond connection. The method is performed on a wire bonding machine and the method includes providing a semiconductor assembly, the assembly comprising a semiconductor die mounted to a substrate and wherein the die and the substrate each have bonding pads associated therewith. The method performs bonding a wire to a first one of the bonding pads to form a first wire bond and thereafter there is performed a process of applying a shear force to the first wire bond with a jaw that engages the first wire bond. Next the method generates a fault signal when a sensor provides a signal indicative of the first wire bond moving during application of the shear force.

In a further embodiment of the present invention there is provided a method for testing a wire bond connection s. The method is performed on a wire bonding machine and the method includes providing a semiconductor assembly, the assembly comprising a semiconductor die mounted to a substrate and wherein the die and the substrate each have bonding pads associated therewith. There is also performed a process of electrically connecting, with a bond wire, one of the bonding pads on the substrate to one of the bonding pads on the die. One end of the bond wire forms a first wire bond with one of the bonding pads on the die and an opposite end of the bond wire forms a second wire bond with one of the bonding pads on the substrate. Applying a shear force to a selected one of the wire bonds is then performed. A generating of a fault signal occurs when a sensor provides a signal indicative of the selected one of the wire bonds moving during application of the shear force.

In another embodiment of the present invention there is provided a wire bonding machine that has a processor, a wire bonding tool and wire bonding tool controller operatively coupled to both the processor and the wire bonding tool. There is a force sensor operatively coupled to the processor and physically associated with a wire bonding jaw of the wire bonding tool. In operation, after the wire bonding tool has made a wire bond on a bonding pad, the wire bonding tool controller controls the wire bonding jaw to apply a shear force to the wire bond, and in response the processor tests a sensing signal from the force sensor to determine if the sensing signal has reached a threshold level. The processor generates a fault signal when the sensing signal is below the threshold level.

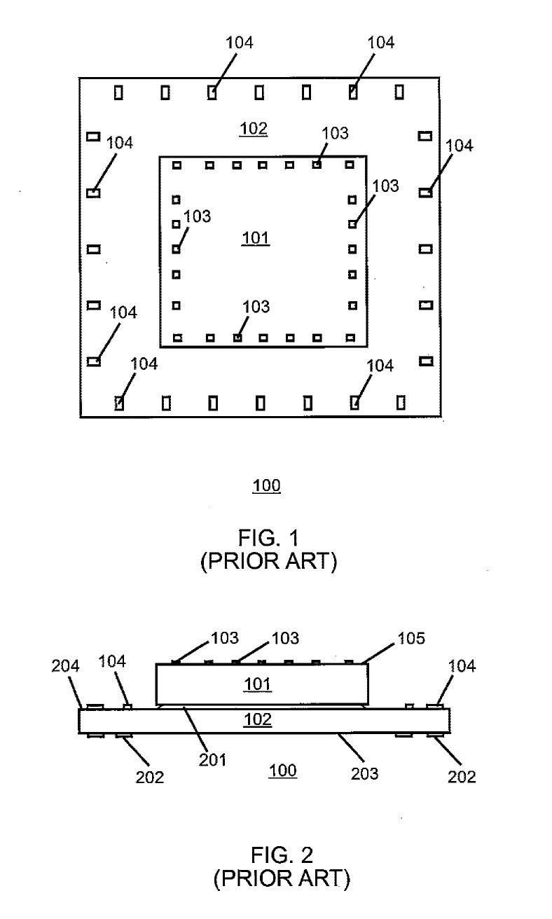

Referring to FIG. 1, a plan view of a known often used semiconductor assembly 100 is shown. The assembly 100 includes a semiconductor die 101 mounted to a substrate 102 and both the die 101 and the substrate 102 each have associated bonding pads 103, 104 on and typically protruding from their respective bond pad surfaces 105, 106.

FIG. 2 shows a side view of the semiconductor assembly 100. As shown, the semiconductor die 101 is mounted on the substrate 102 with a deposit of an epoxy or other form of adhesive 201. The bonding pads 104 associated with the substrate 102 are coupled to respective external connection pads 202 on or protruding from an external connector surface 203 of the substrate 102. The external connector surface 203 is opposite a bond pad surface 204 and the bonding pads 104 are coupled to their respective external connection pads 203 by conductive vias or conductive runners (not shown) as will be apparent to a person skilled in the art.

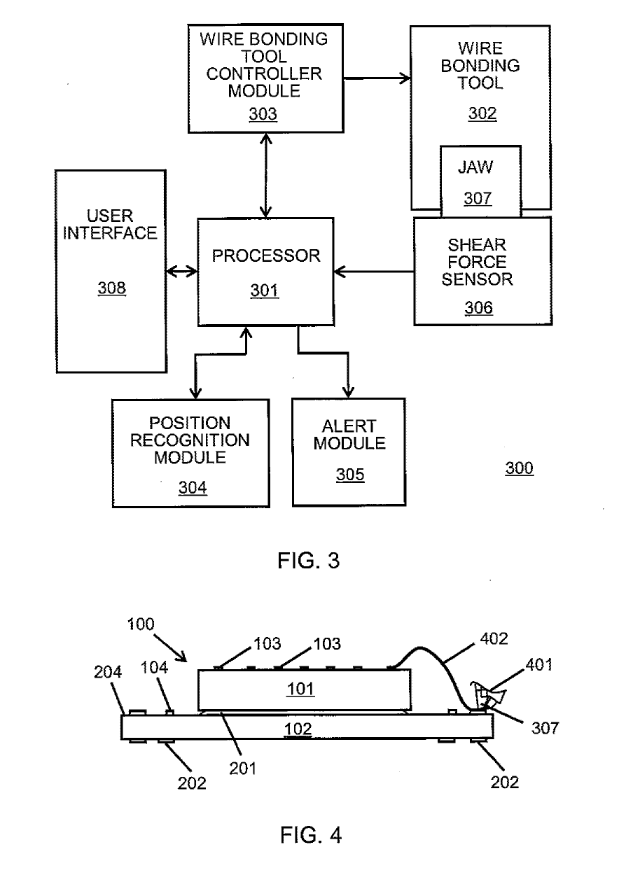

FIG. 3 illustrates a schematic block diagram of a wire bonding machine 300 in accordance with a preferred embodiment of the present invention. The wire bonding machine 300 includes a processor 301 and a wire bonding tool 302. There is also a wire bonding tool controller module 303 that is operatively coupled to both the processor 301 and the wire bonding tool 302. There is a position recognition module 304, alert module 305, shear force sensor 306 and user interface 308 which are all operatively coupled to the processor 301. The shear force sensor 306 is also physically associated with (mechanically attached to) a wire bonding jaw 307 of the wire bonding tool 302. Furthermore, in this embodiment the shear force sensor 306 is a strain gauge that measures strain and provides a sensing signal St that is proportional to a shear force Fs on the jaw 307.

In operation, after the wire bonding tool 302 has made a wire bond on a bonding pad (103, 104), the wire bonding tool controller module 303 controls the wire bonding jaw 307 to apply the shear force Fs to the wire bond. In response, the processor 301 tests the sensing signal St from the shear force sensor 306 to determine if the sensing signal St has reached a threshold level Th. The sensing signal St is indicative of the shear force Fs and the processor 301 generates a shear test fail signal Sf when the sensing signal St is below the threshold level Th. The shear test fail signal Sf is sent to the alert module 305 which thereby typically alerts an operator or alternatively automatically determines a suitable course of action.

The position recognition module 304 typically employs imaging to determine the position of the jaw 307 relative to a bonding pad (103, 104). The position recognition module 304 thereby sends positional information to the processor 301, which sends information or instructions to the wire bonding tool controller module 303, in order for accurate placement and bonding of wire bonds to the bonding pads (103, 104).

FIG. 4 illustrates part of the wire bonding tool 302 when performing wire bonding of the semi conductor assembly 100. The part of the wire bonding tool 302 is a wire bonding tool head 401 that includes the jaw 307. As illustrated, the wire bonding tool head 401 has completed bonding of a bonding wire 402 to a selected pair of bonding pads (103, 104). This bonding process is known to a person skilled in the art and therefore requires no further description.

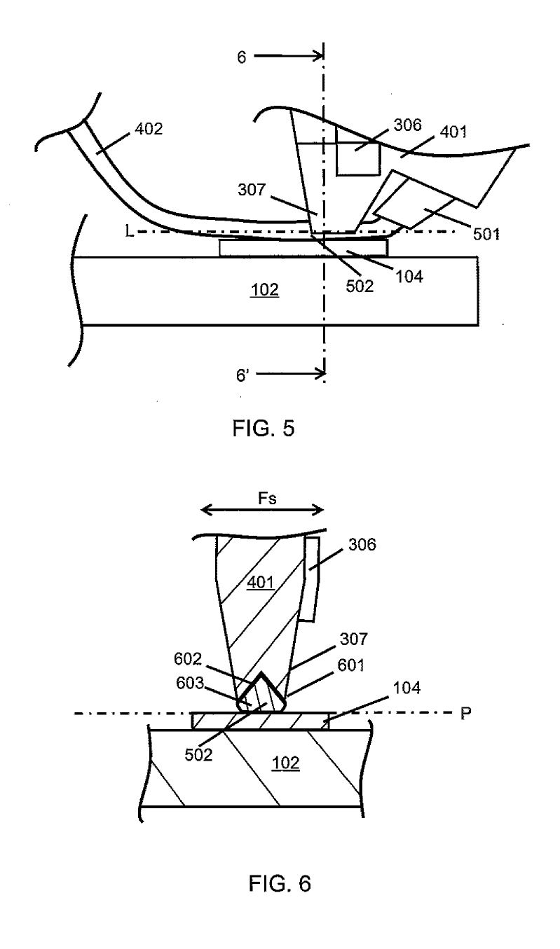

FIG. 5 illustrates part of the wire bond tool head 401 performing wire bonding in accordance with a preferred embodiment of the present invention. The wire bond tool head 401 includes the wire bonding jaw 307 and a suitably positioned capillary (wire dispenser) 501. Also, the shear force sensor 306 is mounted on a side of the fire bonding tool head 401 at a location proximal to the jaw 307. The wire bond tool head 401 forms a bond 502 that has a longitudinal axis L.

Referring to FIG. 6, a cross-sectional side view of part of the wire bonding tool head 401 through 6-6′ is illustrated. As shown, the wire bonding jaw 307 is shaped to perform wedge bonding. More specifically, the wire bonding jaw 307 has a bonding tip 601 that is recessed with an apexed cavity 602 so that a bonding section 603 of the bonding wire 402 is shaped to resemble a wedge. The shear force sensor 306 is positioned in close proximity to the bonding tip 601. On the side of the wire bonding tool head 401 in order to detect shear forces applied to the wire bonding tool head 401 and wire bond bonding jaw 307 by application of a shear force Fs in either of the directions indicated. This shear force Fs is applied at an angle normal to the longitudinal axis L of the bond 502 and in a plane parallel to a plane P of a bonding surface of the bonding pad 104. Although, as illustrated the wire bonding tool head 401 is over a wire bond 502 on one of the bonding pads 104, it will be apparent to a person skilled in the art that wire bonding tool head 401 could also be over a wire bond 502 on one of the bonding pads 103.

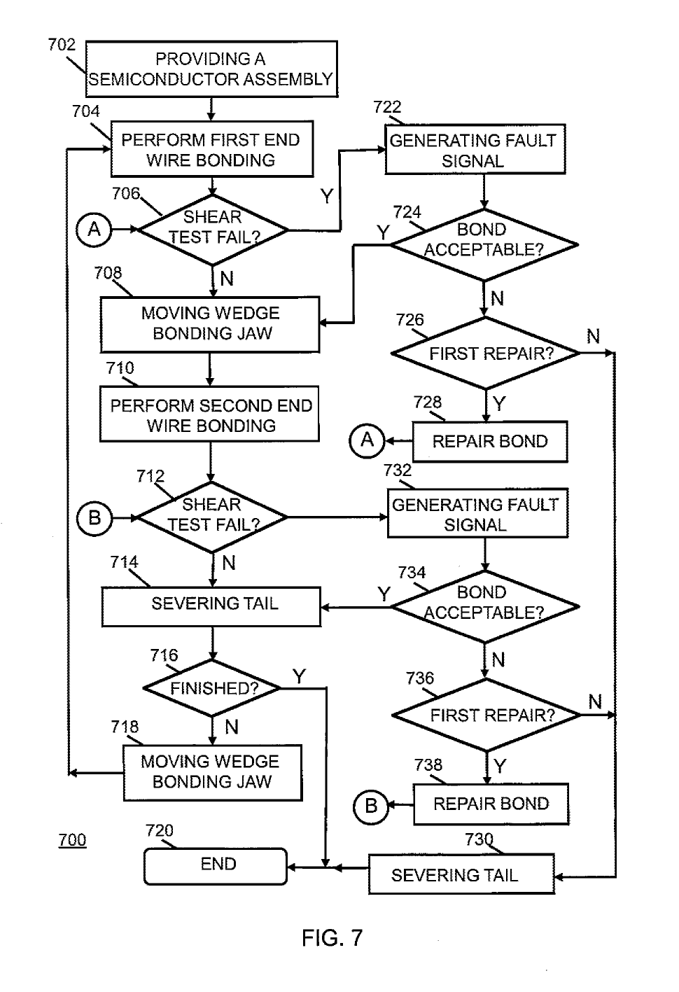

FIG. 7 is a flow chart illustrating a method 700 for testing a wire bond connection in accordance with a preferred embodiment of the present invention. The method 700 is initiated, at a block 702, by providing the semiconductor assembly 100 that includes the semiconductor die 101 mounted to the substrate 102. At a perform first end wire bonding block 704 the method 700 performs bonding a bonding wire (e.g. 402) to a first one of the bonding pads 103 to form a first wire bond B1. The bonding of the bonding wire is performed by the wire bonding jaw 307 which in this embodiment performs wedge bonding of the bonding wire to the first one of the bonding pads 103.

At a shear test fail detection block 706 the method 700 performs a process of applying the shear force Fs to the first wire bond B1 with the wire bonding jaw 307 that engages the first wire bond B1. The shear force Fs is applied by the wire bonding jaw 307 at an angle normal to the longitudinal axis L of the first wire bond B1 and in a plane parallel to plane P of the bonding surface of the bonding pad 103. If the shear force sensor 306 provides the sensing signal St that achieves a signal level above the threshold level Th, then the processor 301 determines that the first wire bond B1 has passed the shear test and the method 700 therefore continues the general wire bonding process at a moving block 708. However, if the shear force sensor 306 provides the sensing signal St with a signal level below the threshold level Th, then the processor 301 determines that the first wire bond B1 has failed the shear test. It will be apparent to a person skilled in the art that the first wire bond B1 fails the shear test when the jaw 307 is insufficiently stressed which is therefore indicative of the first wire bond B1 moving (shearing) during application of the shear force Fs.

When the shear test fail detection block 706 determines that the first wire bond B1 has failed the shear test, the processor 301 signals the alert module 305 with the shear test fail signal Sf. Thus, at a block 722, the method 700 generates a fault signal. A bond assessment test is performed, at a bond acceptable test block 724, in which an operator can input an accept bond or a reject bond instruction via the user interface 308. If the first wire bond B1 is acceptable the processor 301 signals the tool controller module 303 to move the wedge bonding jaw 307 at the moving block 708. Alternatively, if the first wire bond B1 is unacceptable (and therefore rejected) the processor 301 signals the tool controller module 303 to repair the bond by attempting to re-bond the first wire bond B1 at a repair bond block 728. This repair at the repair bond block 728 is only performed if it is the first repair of the first wire bond B1 as determined by a simple counter assessed at a first repair test block 726.

After the attempt to repair the first wire bond B1, by re-performing wire bonding, the method 700 returns to the shear test fail detection block 706 to assess the shear test integrity of the first wire bond B1. When the method 700 reaches the moving block 708, the wire bonding jaw 307 moves to a second one of the bonding pads 104 and the bonding wire 402 is dispensed through the capillary 501. Accordingly, the bonding wire 402 bridges the bonding pad 103 of the bond B1 to the second one of the bonding pads 104.

At a second end wire bonding block 710 the method 700 performs bonding the bonding wire 402 to the second one of the bonding pads 104 to form a second wire bond B2. After completion of the bonding of block 710, the bonding wire 402 electrically connects the first one of the bonding pads 103 to the second one of the bonding pads 104. Next, at a shear test fail detection block 712 the method 700 performs a process of applying the shear force Fs to the second wire bond B2 with the wire bonding jaw 307 that engages the second wire bond B2. As above, the shear force Fs is applied by the wire bonding jaw 307 at an angle normal to the longitudinal axis L of the second wire bond B2 and in a plane parallel to plane P of the bonding surface of the bonding pad 104. If the shear force sensor 306 provides the sensing signal St that achieves a signal level above the threshold level Th, then the processor 301 determines that the second wire bond B2 has passed the shear test and the method 700 therefore continues the general wire bonding process at a severing tail block 714. However, if the shear force sensor 306 provides the sensing signal St with a signal level below the threshold level Th, then the processor 301 determines that the second wire bond B2 has failed the shear test. In this regard, the second wire bond B2 fails the shear test when the jaw 307 is insufficiently stressed which is therefore indicative of the second wire bond B1 moving (shearing) during application of the shear force Fs.

When the shear test fail detection block 712 determines that the second wire bond B2 has failed the shear test, the processor 301 signals the alert module 305 with the shear test fail signal Sf. Thus, at a block 732, the method 700 generates a fault signal. A bond assessment test is performed, at a bond acceptable test block 734, in which an operator can input an accept bond or a reject bond instruction via the user interface 308. If the second wire bond B2 is acceptable the processor 301 signals the tool controller module 303 sever the tail of the bonding wire 402, at the severing tail block 714, as the wire bonding between the two pads 103 and 104 has been completed. Alternatively, if the second wire bond B2 is unacceptable (and therefore rejected) the processor 301 signals the tool controller module 303 to repair the bond by attempting to re-bond the second wire bond B2 at a repair bond block 738. This repair at the repair bond block 738 is only performed if it is the first repair of the second wire bond B2 as determined by a simple counter assessed at a first repair test block 736.

After the attempt to repair the second wire bond B2, by re-performing wire bonding, the method 700 returns to the shear test fail detection block 712 to assess the shear test integrity of the second wire bond B2. When the method 700 reaches the severing tail block 714, the tool head 401 severs the tail of the bonding wire 402 to complete the wire bonding between the two pads 103 and 104. The method 700 then determines, at a finished test block 716, if it has finished all wire bonds for the semiconductor assembly 100. If the method 700 determines that it has finished all wire bonds for the semiconductor assembly 100, it terminates (or alternatively moves to wire bond and shear test another semiconductor assembly 100) at an end block 720. However, if there are further wire bonds required for the current assembly 100 being bonded, the method 700 moves the bonding jaw 307, at a moving block 718, to another one of the pads 103 (selected pad) that still require wire bonding. The method 700 then returns to block 704 to perform wire bonding on this selected pad.

It should be noted that if the first repair test block 726 determines that there has been a previous attempt to repair the first wire bond B1 the method 700 goes to a severing tail process of block 730. Similarly, if the first repair test block 736 determines that there has been a previous attempt to repair the second wire bond B2 the method 700 will also goes to a severing tail process of block 730. The severing tail process of block 730 performs a severing of the bonding wire 402, with the tool head 401, to remove the bonding wire 402 from what is determined to be a poor quality wire bonded pad. The severing is thus required to allow the wire bonding machine to continue wire bonding further semiconductor assemblies and therefore the method 700 terminates at the end block 720.

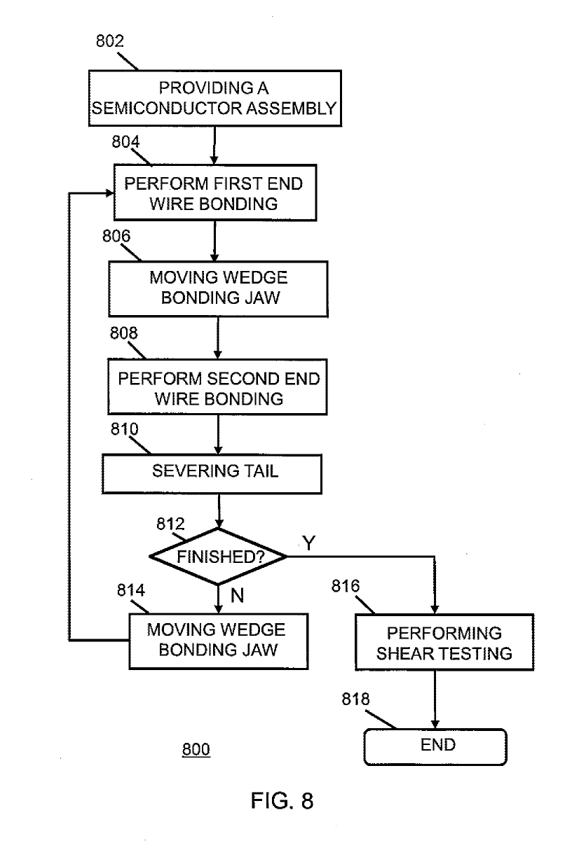

The method 700 applies the shear force Fs to the first wire bond B1 before the process of bonding the wire 402 to the second one of the bonding pads 104. However, in FIG. 8, another method 800 for testing a wire bond connection in accordance with another preferred embodiment of the present invention is illustrated. In the method 800 the applying a shear force Fs to the first wire bond B1 occurs after the process of bonding the bonding wire 402 to the second one of the bonding pads 104. The method 800 is initiated, at a block 802, by providing the semiconductor assembly 100 that includes the semiconductor die 101 mounted to the substrate 102. At a perform first end wire bonding block 804 the method 800 performs bonding a bonding wire 402 to a first one of the bonding pads 103 to form a first wire bond B1. The bonding of the bonding wire is performed by the wire bonding jaw 307 which in this embodiment performs wedge bonding of the bonding wire to the first one of the bonding pads 103.

At a moving block 806 the wire bonding jaw 307 moves to a second one of the bonding pads 104 and the bonding wire 402 is dispensed through the capillary 501. The bonding wire 402 therefore bridges the bonding pad 103 of the bond B1 to the second one of the bonding pads 104. Next, at a perform second end wire bonding block 808 the method 800 performs bonding the bonding wire 402 to the second one of the bonding pads 104 to form a second wire bond B2. After completion of the bonding of block 808, the bonding wire 402 electrically connects the first one of the bonding pads 103 to the second one of the bonding pads 104.

When the method 800 reaches a severing tail block 810, the tool head 401 severs the tail of the bonding wire 402 to complete the wire bonding between the two pads 103 and 104. The method 800 then determines, at a finished test block 812, if it has finished all wire bonds for the semiconductor assembly 100. If it is determined that other pads 103, 103 require wire bonding the wire bonding jaw 307 is moved to another pad 103 at a moving block 814. The method 800 then returns to first end wire bonding block 804 to perform further wire bonding. Alternatively, if the a finished test block 812 determines that the method 800 has finished all wire bonds for the semiconductor assembly 100 the method 800 performs shear testing at a shear testing block 816. The shear testing performed at the shear testing block 816 is similar to the shear testing process as described above and to avoid repetition is not described again. The process of shear testing terminates after: a) all wire bonds of the semiconductor assembly passed the shear test (after re-bonding if required); or shear test failure of a wire bond that was not or could not be repaired. The method 800 then terminates at an end block 818.

In summary, the method 800 performs a process of electrically connecting, with the bond wire 402, one of the bonding pads 104 on the substrate 102 to one of the bonding pads 103 on the die 101. Thus, one end of the bond wire 402 forms the first wire bond B1 with one of the bonding pads 103 or 104 and an opposite end of the bond wire forms a second wire bond with one of the bonding pads 103 or 104. Thereafter, the shear force Fs test is applied to each wire bond after all the pads 103, 104 have been wire bonded or alternatively after two pads have been electrically connected together by a bonding wire 402.

Advantageously the present invention provides for strength testing of wire bond connection s without the need for gripping tools or hooks. The present invention is particular advantageous for wedge bonded connections which have a suitable profile to allow application of the shear force Fs to a bond under test.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A wire bonding machine, comprising:
a processor;
a wire bonding tool;
a wire bonding tool controller operatively coupled to both the processor and the wire bonding tool; and
a force sensor operatively coupled to the processor and physically associated with a wire bonding jaw of the wire bonding tool,
wherein, in operation, after the wire bonding tool forms a wire bond on a bonding pad, the wire bonding tool controller controls the wire bonding jaw to apply a shear force to the wire bond, and in response the processor tests a sensing signal from the force sensor to determine if the sensing signal has reached a threshold level, and wherein the processor generates a fault signal when the sensing signal is below the threshold level.

2. The wire bonding machine of claim 1, wherein the wire bonding jaw is shaped to perform wedge bonding.

3. The wire bonding machine of claim 1, wherein the sensor is a strain gauge that measures strain proportional to the shear force on the jaw.

4. The wire bonding machine of claim 1, wherein, in operation, the shear force is applied at an angle normal to a longitudinal axis of the bond.

5. The wire bonding machine of claim 1, wherein, in operation, the shear force is applied in a plane parallel to a bonding surface of the bonding pad.

6. A method for testing a wire bond connection, the method being performed using a wire bonding machine, the method comprising:
providing a semiconductor assembly, the assembly comprising a semiconductor die mounted to a substrate, wherein the die and the substrate each have bonding pads associated therewith;
bonding a wire to a first one of the bonding pads to form a first wire bond;
applying a first shear force to the first wire bond with a jaw that engages the first wire bond; and
generating a first fault signal when a sensor provides a signal indicative of the first wire bond moving during application of the shear force.

7. The method for testing a wire bond connection of claim 6, wherein the bonding is performed by the jaw.

8. The method for testing a wire bond connection of claim 7, wherein the jaw performs wedge bonding of the wire.

9. The method for testing a wire bond connection of claim 6, wherein the first shear force is applied at an angle normal to a longitudinal axis of the bond.

10. The method for testing a wire bond connection of claim 9, wherein the first shear force is in a plane parallel to a bonding surface of the bonding pads.

11. The method for testing a wire bond connection of claim 6, further including:
bonding the wire to a second one of the bonding pads to form a second wire bond, wherein the wire electrically connects the first one of the bonding pads to the second one of the bonding pads;
applying a second shear force to the second wire bond with a jaw that engages the second wire bond; and
generating a second fault signal when the sensor provides a signal indicative of the second wire bond moving during application of the shear force.

12. The method for testing a wire bond connection of claim 11, wherein the applying the first shear force to the first wire bond occurs before the process of bonding the wire to the second one of the bonding pads.

13. The method for testing a wire bond connection of claim 11, wherein the applying the first shear force to the first wire bond occurs after the process of bonding the wire to the second one of the bonding pads.

14. The method for testing a wire bond connection of claim 11, wherein in response to the second fault signal the method performs the step of re-bonding the second wire bond.

15. The method for testing a wire bond connection of claim 6, wherein in response to the first fault signal the method performs the step of re-bonding the first wire bond.

16. A method for testing wire bond connections, the method being performed on a wire bonding machine, the method comprising:
providing a semiconductor assembly including a semiconductor die mounted on a substrate, wherein both the die and the substrate have bonding pads associated therewith;
electrically connecting, with a bond wire, one of the die bonding pads to one of the substrate bonding pads, wherein one end of the bond wire forms a first wire bond with one of the die bonding pads and an opposite end of the bond wire forms a second wire bond with one of the substrate bonding pads;
applying a shear force to a selected one of the wire bonds; and
generating a fault signal when a sensor provides a signal indicative of the selected one of the wire bonds moving during application of the shear force.

17. The method for testing wire bond connections of claim 16, wherein the bonding is wedge bonding performed by a jaw that also applies the shear force.

18. The method for testing wire bond connections of claim 16, wherein the shear force is applied at an angle normal to a longitudinal axis of the bond.

19. The method for testing wire bond connections of claim 16, wherein the sensor is a strain gauge that measures strain proportional to the shear force on the jaw.

20. The method for testing wire bond connections of claim 16, wherein in response to the fault signal the method performs the step of re-bonding the selected one of the wire bonds.
